(19) United States
(12) Patent Application Publication
(10) Pub. No.: US 2005/0073031 A1
(43) Pub. Date: Apr. 7, 2005

(54) Lead frame, semiconductor device, and method for manufacturing semiconductor device

(75) Inventors: Shunichi Abe, Tokyo (JP); Kouji Yufu, Tokyo (JP); Naoki Izumi, Tokyo (JP); Akira Yamazaki, Tokyo (JP)

Correspondence Address: McDermott, Will & Emery, 600 13th Street, N.W., Washington, DC, 20005-3096, US

(73) Assignee: RENESAS TECHNOLOGY CORP.

(21) Appl. No.: 10/958,300

(22) Filed: Oct. 6, 2004

(30) Foreign Application Priority Data
Oct. 6, 2003 (JP) 2003-347120

(51) Int. Cl. H01L 23/495

(52) U.S. Cl. 257/666

(57) ABSTRACT

In a lead frame used in a molded package of a semiconductor device, leads disposed entirely including an island portion, which is a portion for mounting a semiconductor chip, are formed. In the manufacture of a semiconductor device, after mounting the semiconductor chip and performing wire bonding and resin sealing, the leads are adequately cut corresponding to the number of electrodes of the semiconductor chip to divide the leads into a plurality of portions.

### BACKGROUND OF THE INVENTION

1. Field of the Invention

The present invention relates to a lead frame, a semiconductor device, and a method for manufacturing a semiconductor device. More specifically, the present invention relates to a lead frame used in the molded package of a semiconductor integrated circuit, a semiconductor device using such a lead frame, and a method for manufacturing such a semiconductor device.

2. Background Art

Presently, various types of surface-mounted packages are used in semiconductor devices. One of the surface-mounted packages is a package known as a QFN (quad flat non-leaded package).

A QFN has no lead pins on the four sides thereof, and a lead frame, which becomes external terminals, is exposed on the bottom surface of the semiconductor device. Therefore, the QFN is superior to a QFP (quad flat package) having lead pins on the four sides in both the mountable area and the height. The QFN is also advantageous because a plurality of semiconductor chips can be mounted.

In recent years, however, increase in the number of external terminals has been demanded to cope with increase in the number of pins of a semiconductor chip. Therefore, various techniques to increase the number of leads in a lead frame have been proposed also for QFNs.

In QFNs, however, leads are arrayed in the peripheral portions of the bottom surface of a semiconductor device outside the of semiconductorchip. Therefore, if thenumberof external terminals is increased, the size of the entire semiconductor device must be enlarged.

### SUMMARY OF THE INVENTION

Therefore, the present invention is intended to solve the above-described problems, and to provide a lead frame, a semiconductor device, and a method for manufacturing a semiconductor device that can secure a required number of external terminals corresponding to the number of terminals in the semiconductor device, while suppressing the enlargement of the package.

According to one aspect of the present invention, a lead frame used in the mold package of a semiconductor device, comprises a lead to be terminals in the semiconductor device. The lead can be divided by cutting into a plurality of parts that can be used as terminals.

According to another aspect of the present invention, a semiconductor device comprises a semiconductor chip, a lead frame, gold wires and a sealing member. The semiconductor chip has a plurality of bonding pads. The lead frame mounts the semiconductor chip, and includes a lead to become terminals in the semiconductor device. The gold wires electrically connect the bonding pads to predetermined locations of the lead. The sealing member seals the semiconductor chip on the lead frame. The lead is divided into a predetermined number at predetermined locations after mounting the semiconductor chip, and are used as individual terminals corresponding to the bonding pads in a one-to-one manner.

According to another aspect of the present invention, in a method for manufacturing a semiconductor device, a semiconductor chip that has a plurality of bonding pads is mounted on a predetermined location of a lead frame. The bonding pads are connected to a lead of the lead frame by a gold wire. The semiconductor chip is sealed on the lead frame using a sealing member. The lead frame is cut on the predetermined location to divide the lead into individual terminals corresponding to the bonding pads in a one-to-one manner.

Other and further objects, features and advantages of the invention will appear more fully from the following description.

### BRIEF DESCRIPTION OF THE DRAWING

FIGS. 1A and 1B are schematic diagrams for illustrating a semiconductor device 100 in the first embodiment of the present invention;

FIG. 2 is a schematic top view for illustrating a lead frame 110 used in the semiconductor device 100 in the first embodiment of the present invention;

FIG. 3 is a flow diagram for illustrating the method for manufacturing a semiconductor device 100 according to the first embodiment of the present invention;

FIGS. 4A to 7B are schematic diagrams for illustrating the state of the semiconductor device 100 in each manufacturing step;

FIGS. 8A and 8B are schematic diagrams for illustrating a semiconductor device 200 according to the second embodiment of the present invention;

FIG. 9 is a schematic diagram for illustrating a lead frame 210 used in a semiconductor device 200 according to the second embodiment of the present invention;

FIGS. 10A to 12B are schematic diagrams for illustrating the state in each step for manufacturing a semiconductor device 200 according to the second embodiment of the present invention;

FIGS. 13A and 13B are schematic diagrams for illustrating a semiconductor device 300 according to the third embodiment of the present invention;

FIG. 14 is a schematic diagram for illustrating a lead frame 310 used in the semiconductor device 300 in the third embodiment of the present invention;

FIGS. 15A and 15B are schematic diagrams for illustrating another semiconductor device according to the third embodiment of the present invention;

FIG. 16 is a schematic sectional view for illustrating the semiconductor device 400 according to the fourth embodiment of the present invention;

FIG. 17 is an enlarged side view of the semiconductor device 400 according to the fourth embodiment of the present invention.

FIG. 18 is a schematic top view for illustrating a lead frame 410 used in the semiconductor device 400 in the fourth embodiment of the present invention;

FIG. 19 is a flow diagram for illustrating the method for manufacturing a semiconductor device 400 according to the fourth embodiment of the present invention;

FIGS. 20 to 22 are schematic diagrams for illustrating the state of the semiconductor device 400 in each manufacturing step.

### DESCRIPTION OF THE PREFERRED EMBODIMENT

The embodiments of the present invention will be described below referring to the drawings. In the drawings, the same or corresponding parts will be denoted with the same reference numerals, and the description thereof will be simplified or omitted.

### First Embodiment

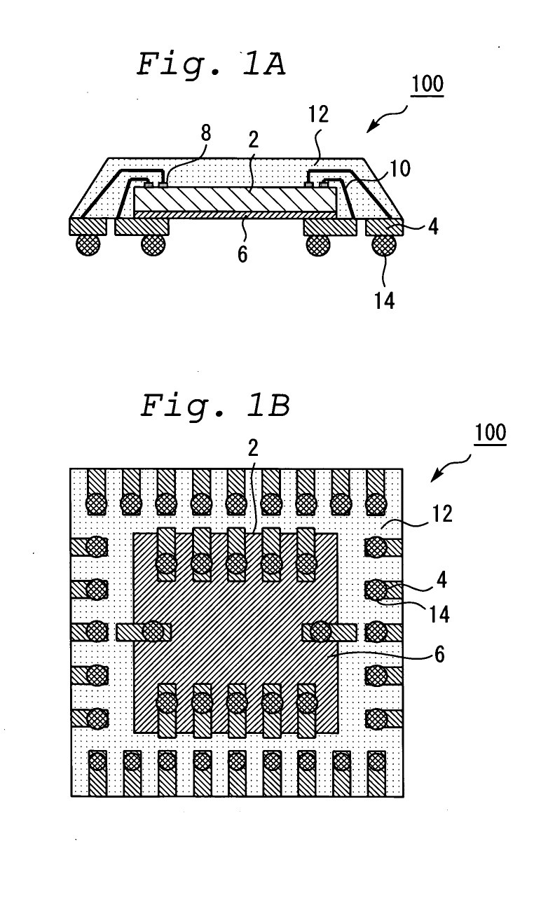

FIGS. 1A and 1B are schematic diagrams for illustrating a semiconductor device 100 in the first embodiment of the present invention, FIG. 1A illustrating a cross section and FIG. 1B illustrating a lower surface.

For the convenience of description, the upper surface in FIG. 1A, which is the major surface side wherein the electrodes of the of semiconductor chip 2 and the like are formed, is referred to as “the front surface”; and the lower surface FIG. 1A is referred to as “the bottom surface”. The direction along to two sides facing up and down on the bottom surface of the semiconductor device in FIG. 1B is referred to as “the lateral direction”, and the direction perpendicular to the lateral direction is referred to as “the vertical direction”.

As FIG. 1A illustrates, in the semiconductor device 100, a semiconductor chip 2 is mounted on leads 4 through a die bonding material 6. Bonding pads 8 which are the electrodes on the semiconductor chip 2 are connected to leads 4, which become terminals in the semiconductor device 100, with gold wires 10. The semiconductor chip 2 is sealed with a sealing resin 12 in the state thus mounted on the leads 4, and connected with gold wires 10. As FIG. 1B illustrates, leads 4 are exposed on the bottom surface of the semiconductor device 100, and each lead 4 is subjected to plating and provided with exterior plating 14.

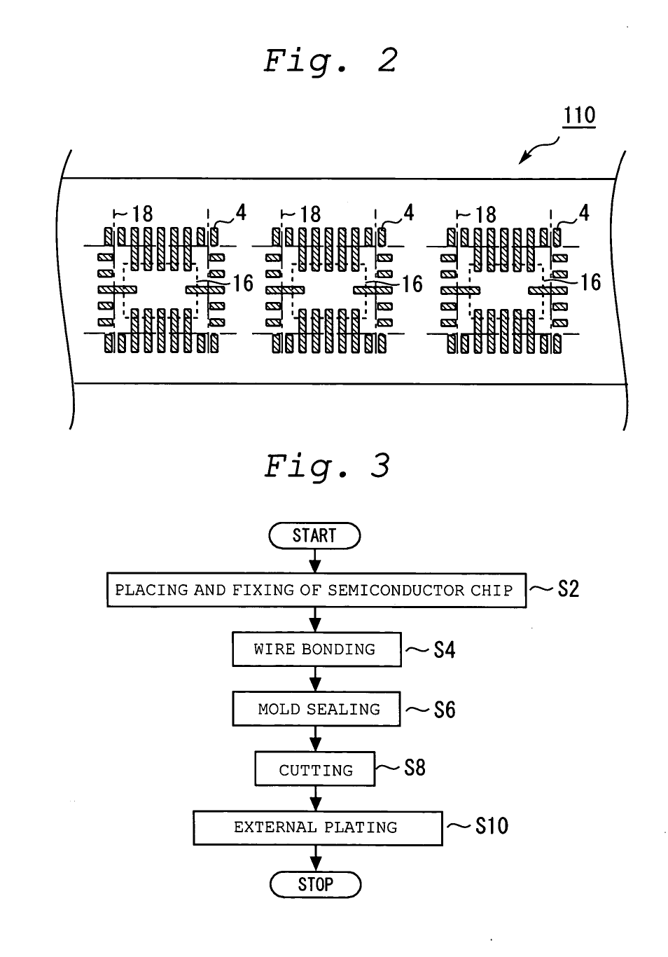

FIG. 2 is a schematic top view for illustrating a lead frame 110 used in the semiconductor device 100 in the first embodiment of the present invention.

As FIG. 2 illustrates, a plurality of lead patterns are disposed on the lead frame 110. Each of lead pattern is composed of plurality of leads 4 which are vertically and laterally disposed on the lead frame 110 perpendicularly to each peripheral side of the lead frame 110 in the state wherein leads 4 do not intersect each other. In each of lead patterns, four leads 4 located on each of four corners are constituted to be shorter than others. The rest of leads 4, namely the total of 10 leads 4 disposed in the vertical direction, and the total of two leads 4 disposed in the lateral direction, are constituted to be longer. The long leads 4 are disposed so as to extend from island areas 16, which are the areas for mounting of semiconductor chips 2, to the peripheral portions of the island areas 16.

In each of the lead patterns, two lines in each of vertical and lateral directions, namely the total of four lines, become dicing lines 18. The dicing lines 18 are lines that extend in parallel to each side at the location to contact the ends of short leads 4, and long leads 4 are cut in two portions at this location after the semiconductor device is sealed with a resin.

In the lead frame 110, the plurality of lead patterns of leads 4 arrayed as described above are constituted side by side, and a semiconductor chip 2 can be mounted on each island area 16.

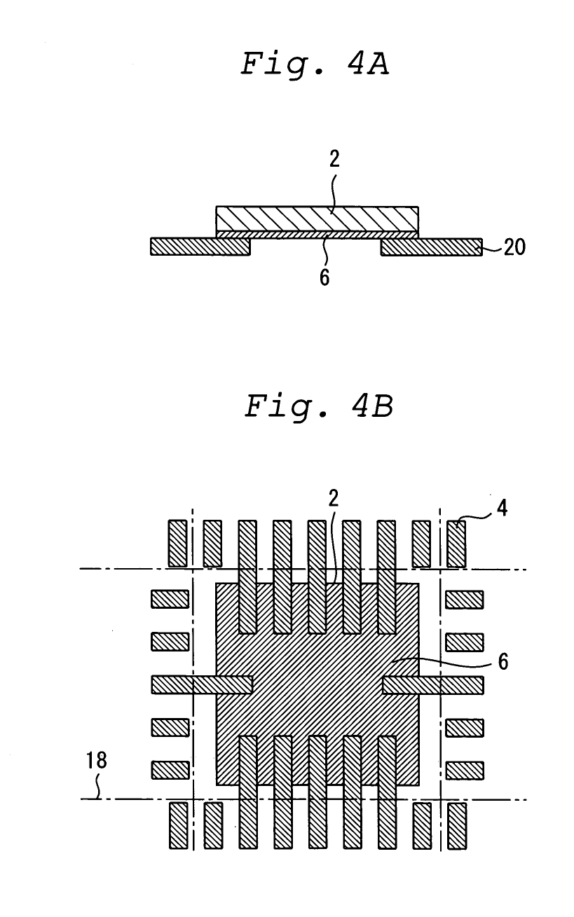

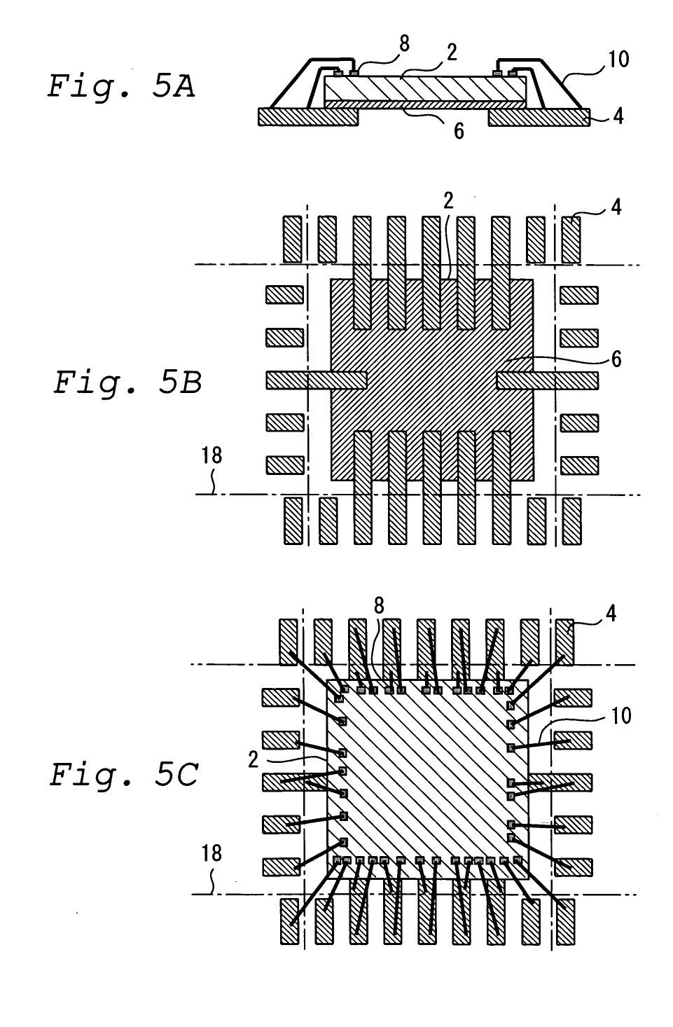

FIG. 3 is a flow diagram for illustrating the method for manufacturing a semiconductor device 100 according to the first embodiment of the present invention. FIGS. 4A to 7B are schematic diagrams for illustrating the state of the semiconductor device 100 in each manufacturing step. In each diagram, FIGS. 4A, 5A, 6A and 7A illustrate the cross section, FIGS. 4B, 5B, 6B and 7B illustrate the bottom surface, and FIG. 5C, illustrates the front surface.

The method for manufacturing the semiconductor device 100 in the first embodiment of the present invention will be described below in detail referring to FIGS. 3 to 7.

First, as FIGS. 4A and 4B illustrate, a semiconductor chip 2 is mounted on the island area 16 of a lead frame 110, and fixed with a die-bonding material 6 (Step S2). At this time, the semiconductor chip 2 is overlaid on the long leads 4.

Next, as FIGS. 5A, 5B and 5C illustrate, the bonding pads 8 on the semiconductor chip 2 are wire-bonded to the leads 4 with gold wires 10 (Step 4). An end of a gold wire 10 is connected to each bonding pad 8 of the semiconductor chip 2. The other end of the gold wire 10 is connected to a lead 4. At this time, two gold wires 10 are connected to different locations of each long lead 4. On the other hand, one gold wire 10 is connected to a location of each short lead 4.

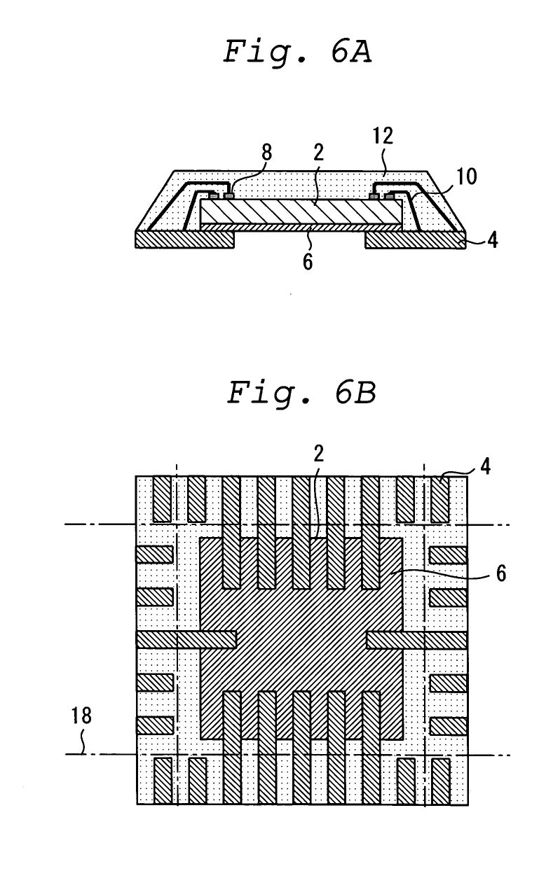

Next, as FIGS. 6A and 6B illustrate, in the state wherein bonding pads 8 and leads 4 are connected with gold wires 10, the semiconductor chip 2 is mold-sealed with a sealing resin 12 on the lead frame 110 (Step S6). Thereby, the semiconductor chip 2 is sealed on the leads 4 of the lead frame 110. At this time, on the bottom surface, the leads 4 are exposed from the sealing resin 12 as FIG. 6B illustrates.

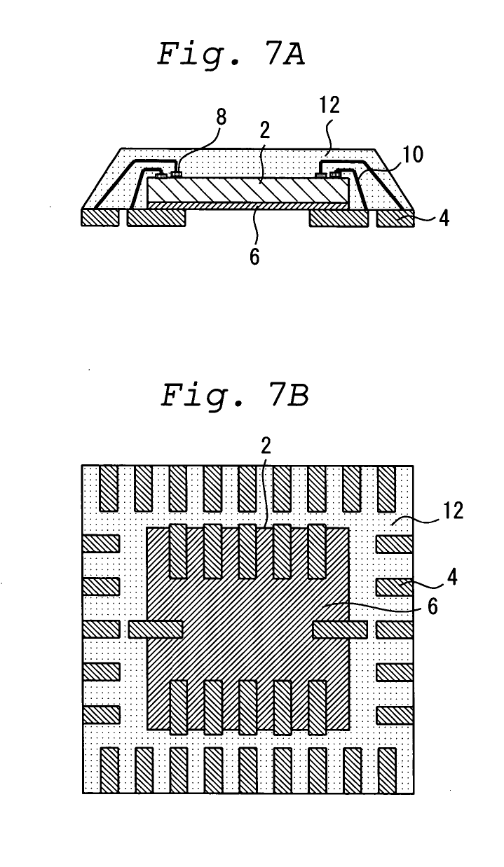

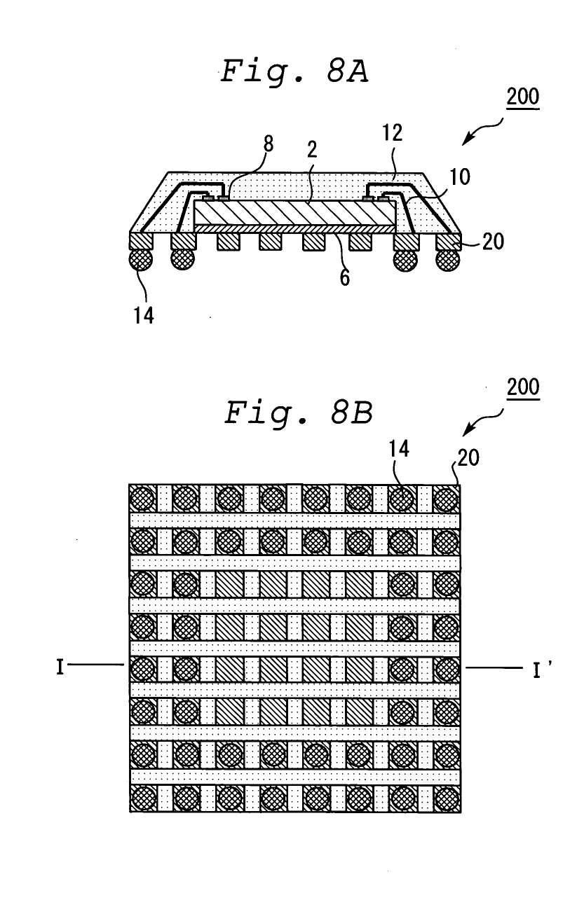

Next, long leads 4 among the leads 4 on the bottom surface are cut in two portions along the dicing lines 18 using a blade (Step S8). Thereby, as FIGS. 7A and 7B illustrate, two bonding pads 8 of the semiconductor chip 2 that have been connected to a long lead 4 are in the state wherein each bonding pad 8 is connected to a cut individual lead 4, and the short-circuited state is released. In the first embodiment, since the dicing lines 18 are in the locations contacting the short leads 4, the short leads 4 are not cut, and stay intact.

Next, each lead 4 is subjected to plating and provided with exterior plating 14 (Step S10). Thereby, a semiconductor device 100 as shown in FIGS. 1A and 1B is completed.

According to the first embodiment, as described above, long leads 4 and short leads 4 are disposed on each of lead patterns in the lead frame 110 in the state wherein the leads 4 do not intersect each other, and the long leads 4 can be cut in two portions, and can be used as separate terminals as required. Therefore, one type of lead frame 110 can be used corresponding to various semiconductor chips having different numbers of bonding pads. Therefore, the productivity of lead frames can be improved, and the cost reduction of semiconductor devices can be achieved.

According to the first embodiment, bonding is performed using long leads 4 as they are, and after mold sealing, the long leads 4 are cut. Therefore, in the lead frame 110, it is not required to previously form leads 4 of complicated arrangement patterns to meet individual of semiconductor chips. Therefore, the productivity of lead frames can be improved, and the cost reduction of semiconductor devices can be achieved.

According to the first embodiment, leads 4 are disposed to underneath the semiconductor chip 2. Therefore, taking the cutting of the leads 4, productivity, and the like into consideration, while securing the length of leads 4 to be long, in the lead, which is a portion close to the semiconductor chip 2 only the space at least required for wire bonding using gold wires 10 can be taken outside the semiconductor chip 2, and the unnecessary portion can be disposed in the space underneath the semiconductor chip 2. Therefore, the space required for the leads 4 can be minimized as much as possible, and the further miniaturization of the semiconductor device 100 can be achieved.

In addition, in the first embodiment, the case wherein only long leads 4 are cut and divided into two portions is described. However, the present invention is not limited thereto, but may include the cases wherein short leads 4 are cut, or long leads 4 are cut into three portions. The number of cutting operations and the locations of cutting can be adjusted considering the number of terminals required for the number of bonding pads in the semiconductor chip 2.

Further in the first embodiment, the lead frame 110 having nine leads 4 in two columns in the vertical direction, a total of 18 leads, and five leads 4 in two rows in the lateral direction, a total of 10 leads; among which four leads 4 located on each of the four corners are shortened, and the rest of the leads 4 are lengthened, is described. However, in the present invention, the number of the leads 4, the ratio of long and short leads 4, and the arrangement pattern of the leads 4 are not limited thereto. The number of the leads 4 or the arrangement pattern of the leads 4 may be selected as required, considering the number and the arrangement of bonding pads 8 in the semiconductor chip 2, or the size of finally formed semiconductor device 100.

Also in the first embodiment, the case wherein leads 4 are cut using a blade or the like is described. However, the present invention is not limited to such a cutting method, but other methods, such as etching, may also be used.

### Second Embodiment

FIGS. 8A and 8B are schematic diagrams for illustrating a semiconductor device 200 according to the second embodiment of the present invention; FIG. 8A illustrating a cross section, and FIGS. 8B illustrating the bottom surface. FIG. 8A shows the cross section in the I-I′ direction in FIG. 8B.

As FIGS. 8A and B illustrate, the semiconductor device 200 is similar to the semiconductor device 100 described in the first embodiment. However, in the semiconductor device 200, the leads 20 are different from leads 4 in the lead frame 110 in the first embodiment, and are formed by grid ironing a lead plate 22. Each lead 20 is subjected to plating and provided with exterior plating 14 as in the first embodiment.

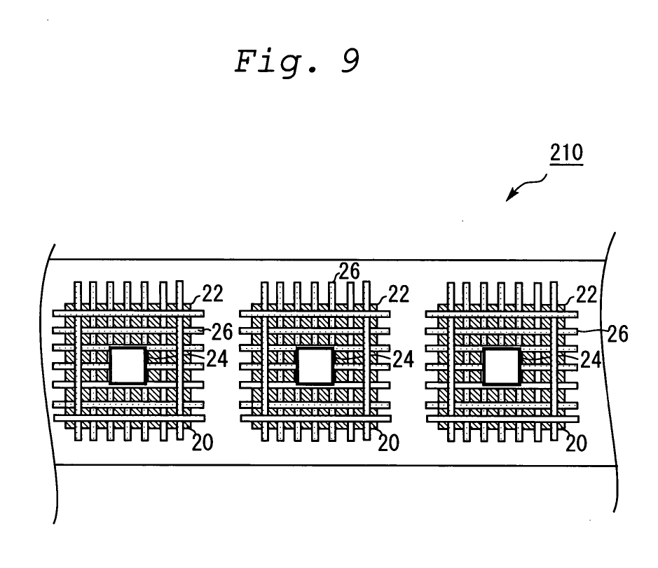

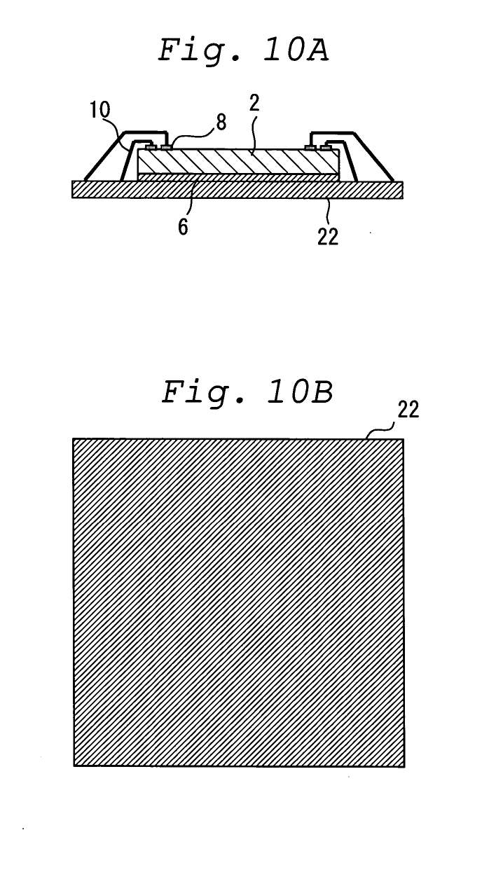

FIG. 9 is a schematic diagram for illustrating a lead frame 210 used in a semiconductor device 200 according to the second embodiment of the present invention.

As FIG. 9 illustrates, a plurality of lead plates 22 are arrayed on the lead frame 210 used in the second embodiment. Each lead plate 22 has an island area 24, which is an area for mounting a semiconductor chip 2. In the second embodiment, seven lines arranged in each of vertical and lateral directions in a lattice pattern become dicing lines 26, and by cutting along the dicing lines 26, the lead plate 22 is divided into leads 20 that become individual terminals.

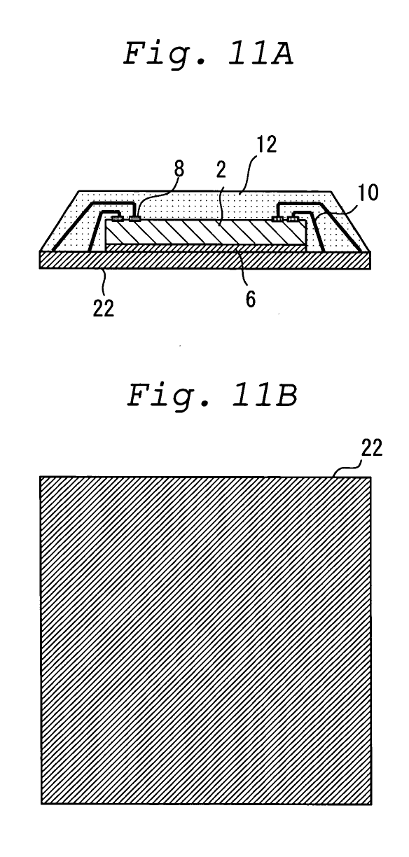

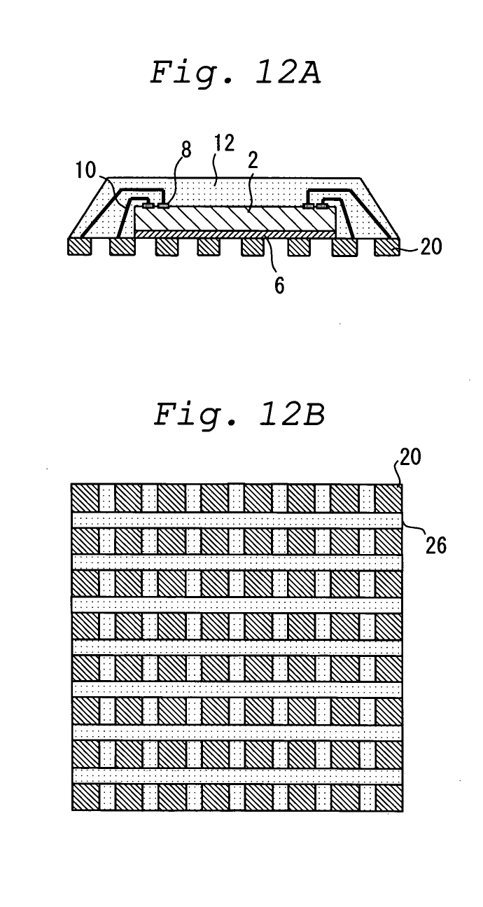

FIGS. 10A to 12B are schematic diagrams for illustrating the state in each step for manufacturing a semiconductor device 200 according to the second embodiment of the present invention. In each drawing, FIGS. 10A, 11A and 12A illustrate the cross section, and FIGS. 10B, 11B and 12B illustrate the bottom surface.

The method for manufacturing the semiconductor device 200 in the second embodiment is the same as the manufacturing method described for the first embodiment. However, in the second embodiment, the dicing lines 26 are different from dicing lines 18 in the cutting step (Step S10) described for the first embodiment.

The method for manufacturing a semiconductor device 200 in the second embodiment will be described below referring to FIGS. 2 and 10A to 12B.

First, a semiconductor chip is mounted on an island area 24 of a lead plate 22, and is fixed using a die-bonding material 6 (Step S2). Next, as FIGS. 10A and 10B illustrate, the bonding pads 8 on the semiconductor chip 2 are connected to the lead plate 22 using gold wires 10 (Step S4). Here, an end of a gold wire 10 is connected to each bonding pad 8 of the semiconductor chip 2. The other end of the gold wire 10 is connected to each location to subsequently become leads 20 formed by cutting the lead plate 22.

Next, as FIGS. 11A and 11B illustrate, mold sealing using the sealing resin 12 is performed in the state wherein gold wires 10 have been connected (Step S6). Thereby, the semiconductor chip 2 is sealed on the lead plate 22. As FIG. 11B illustrates, the lead plate 22 is in an exposed state in the backside of the lead plate 22.

Next, the lead plate 22 is cut along the dicing lines 26 in a lattice pattern (Step S8). Thereby, the lead plate 22 is divided into a required number of leads 20. Thereafter, each lead 20 is subjected to plating and provided with exterior plating 14 (Step S10). Thereby, the semiconductor device 200 as illustrated in FIGS. 8A and 8B is completed.

According to the semiconductor device 200, as described above, the lead plate 22 is cut to use as leads 20. Therefore, one type of lead plate 22 can correspond to a plurality of types of semiconductor chips 2 having different numbers of electrodes. Thereby, the productivity of lead frames 210 is improved, and the production costs of semiconductor device 200 can be lowered.

In the semiconductor device 200, since the lead plate 22 is cut to use as leads 20, no complicated steps for manufacturing the lead frame 210 are required. Therefore, the improvement of the productivity of lead frames 210 can be achieved, leading to the reduction of the production costs of semiconductor devices.

According to the semiconductor device 200, the lead plate 22 exposed on the bottom surface can be cut into leads 20. In the lead plate 22, the parts not required for bonding are disposed under the semiconductor chip 2, and only the parts required for bonding are disposed outside the semiconductor chip 2. Thereby, the size of the semiconductor device 200 can be reduced.

In the second embodiment, the lead plate 22 is divided into eight rows and eight columns of leads 20 by seven dicing lines 26 in each of vertical and lateral directions. However, in the present invention, the number of dicing lines 26 is not limited thereto. The number of dicing lines may be selected as required considering the number and arrangement of bonding pads of the semiconductor chip to be mounted. Therefore, it is not required that the number of dicing lines in the vertical direction is the same as the number of dicing lines in the lateral direction. Also for example, the area of the lead plate 22 not used as the terminals of the island area 24 may not be cut.

Since other parts are same as those in the first embodiment, the description thereof will be omitted.

### Third Embodiment

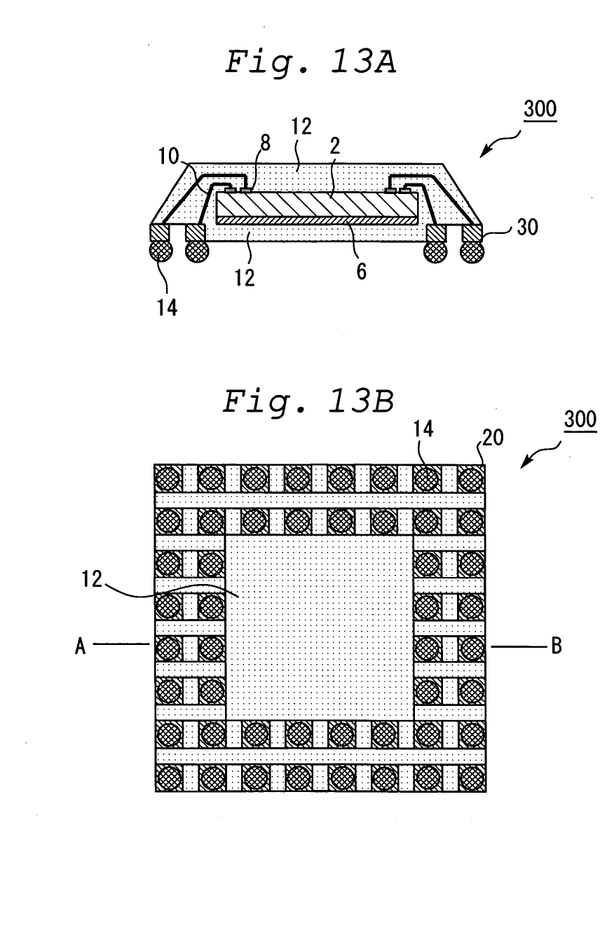

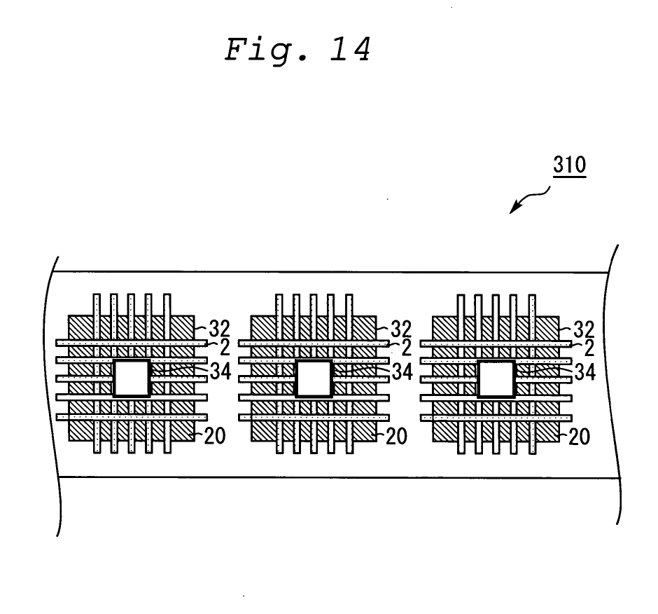

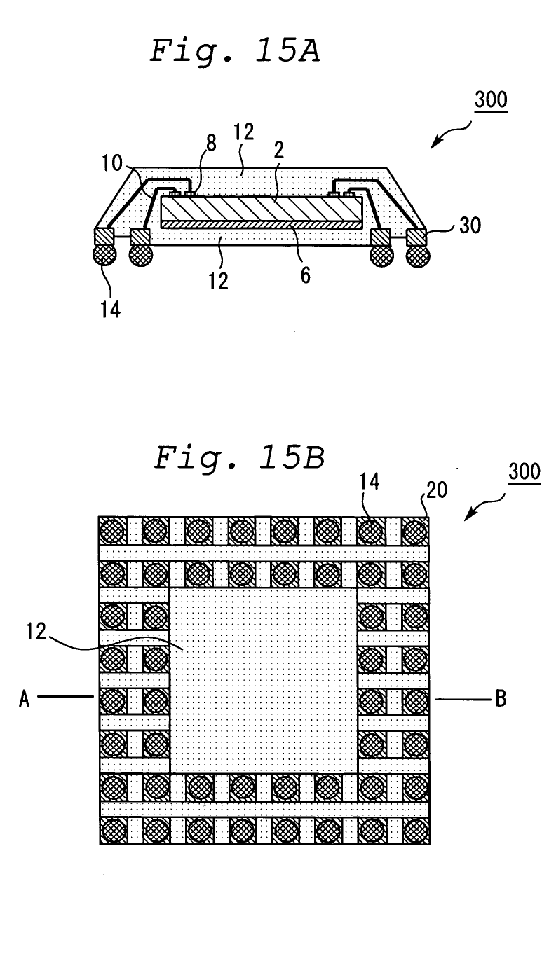

FIGS. 13A and 13B are schematic diagrams for illustrating a semiconductor device 300 according to the third embodiment of the present invention; FIG. 13A illustrating a cross section, and FIG. 13B illustrating the bottom surface. FIG. 14 is a schematic diagram for illustrating a lead frame 310 used in the semiconductor device 300 in the third embodiment of the present invention. FIGS. 15A and 15B are schematic diagrams for illustrating another semiconductor device according to the third embodiment of the present invention; FIG. 15A illustrating a cross section, and FIG. 15B illustrating the bottom surface.

The semiconductor device 300 shown in FIG. 13 is similar to the semiconductor device 200 described in the second embodiment. However, in the semiconductor device 300, there are no leads 30 under the semiconductor chip 2, and the sealing resin 12 is exposed.

As FIG. 14 illustrates, the lead plates 32 in the lead frame 310 are flat plates each having an opening in the center portion, and the opening becomes the island area 34. Therefore, no portions to be leads 30 are formed in the island area 34.

The method for manufacturing a semiconductor device 300 in the third embodiment is the same as the method for manufacturing a semiconductor device 200 described for the second embodiment. However, in the third embodiment, a lead frame 310 having island areas 34 wherein no leads 30 are formed is used as described above. Therefore, in the mold sealing (Step S6) in the third embodiment, a sealing resin 12 is also injected into the portions where no leads 30 are formed. Therefore, as FIGS. 13A and 13B illustrate, the semiconductor device 300 wherein no leads but the sealing resin 12 are exposed on the bottom surface of the semiconductor chip 2.

Thereby, a semiconductor device having the same effect as in the second embodiment can be obtained.

In the third embodiment, no sealing resin 12 is permeated into portions cut along the dicing lines 36 of the lead frame 310, i.e., the portions sandwiched by leads 30 adjacent to each other. However, a trench may be previously formed along the dicing lines 36 on the surface side of the lead frame 310 for injecting the sealing resin 12 into the trench as FIG. 15 illustrates. Thereby the adhesion of the leads 30 and the sealing resin 12 is enhanced, and the reliability of the semiconductor device 300 can be improved.

### Fourth Embodiment

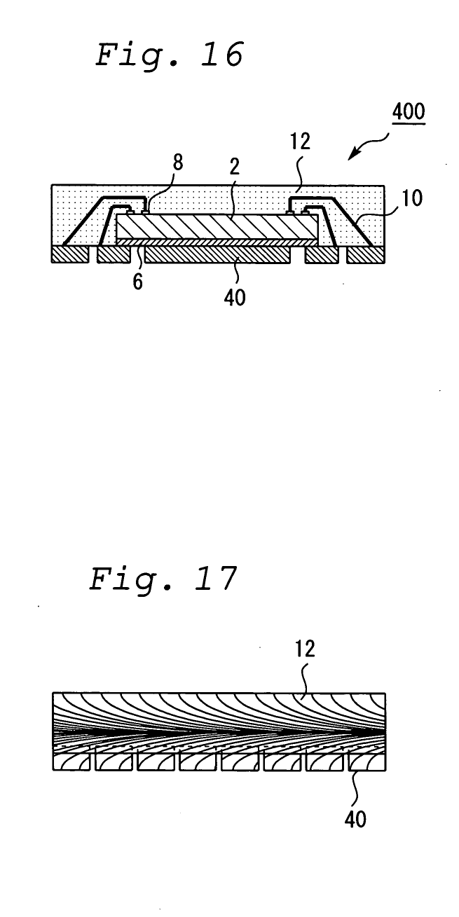

FIG. 16 is a schematic sectional view for illustrating the semiconductor device 400 in the fourth embodiment of the present invention. FIG. 17 is an enlarged side view of the semiconductor device 400.

As FIG. 16 illustrates, in the semiconductor device 400, a semiconductor chip 2 is mounted on a lead frame 410 using a die-bonding material 6. The bonding pads 8 on the semiconductor chip 2 are connected to the leads 40 to become the terminals in the semiconductor device 400 with gold wires 10. The semiconductor chip 2 is sealed with a sealing resin 12 in the state thus mounted on the leads 40 and connected with gold wires 10.

As FIG. 17 illustrates, the marks of the blade are left on the side of the semiconductor device 400. The marks of the blade are left when the leads are cut using the blade from up and down. Therefore, the marks of the blade are left on the sealing resin 12 due to cutting from the front and back directions; and the marks of the blade in one direction are left on the lead frame portion due to cutting from the back direction.

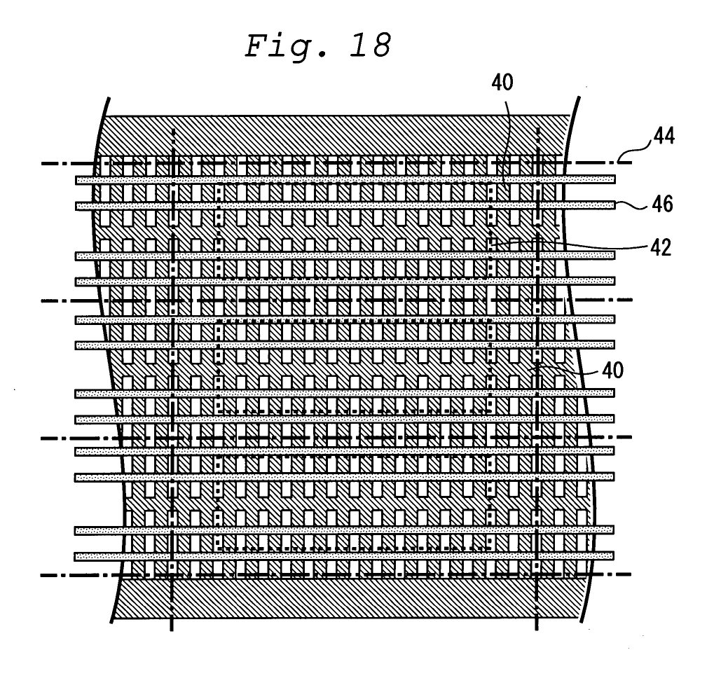

FIG. 18 is a schematic top view for illustrating a lead frame 410 used in the semiconductor device 400 in the fourth embodiment of the present invention.

As FIG. 18 illustrates, three lines of island areas 42 for mounting semiconductor chips 2 are formed on the lead frame 410. The lead frame 410 is cut along chip dicing lines 44 in the vertical and lateral directions, and finally divided into individual semiconductor devices 400.

In the lead frame 410, 16 columns of leads 40 extending in the vertical direction are formed on the areas between two chip-dicing lines 44 in the vertical direction. On the other hand, a line of lead 40 extending in the lateral direction is formed in each of substantial centers of portions between two chip-dicing lines 44 in the lateral direction.

Two lines in each of the areas between a chip-dicing line 44 in the lateral direction and the lead 40 in the lateral direction become lead-dicing lines 46. In the entire lead frame 410, there are a total of 12 lead-dicing lines 46 in the lateral direction. The lead-dicing lines 46 are cutting lines for dividing the lead 40 into leads 40 corresponding to the bonding pads 8 in one-to-one manner. On the surface side for mounting the semiconductor chips 40, a trench (not shown) of a depth of a half the thickness of the lead frame 410 is previously formed in the location to be the lead dicing line 40.

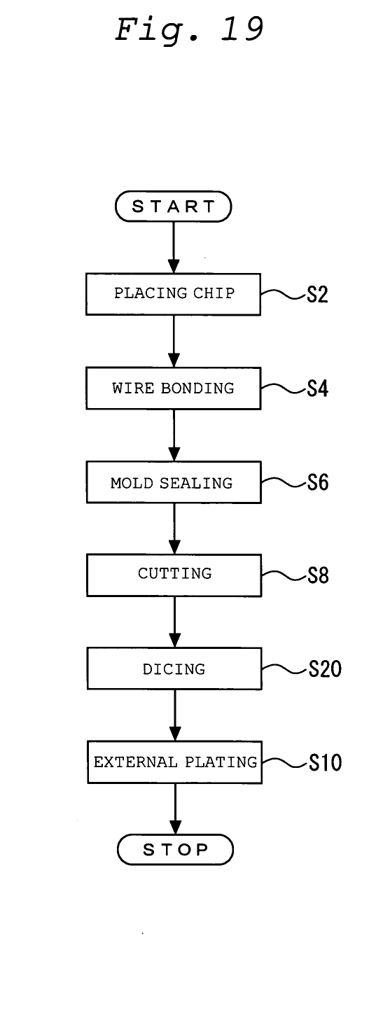

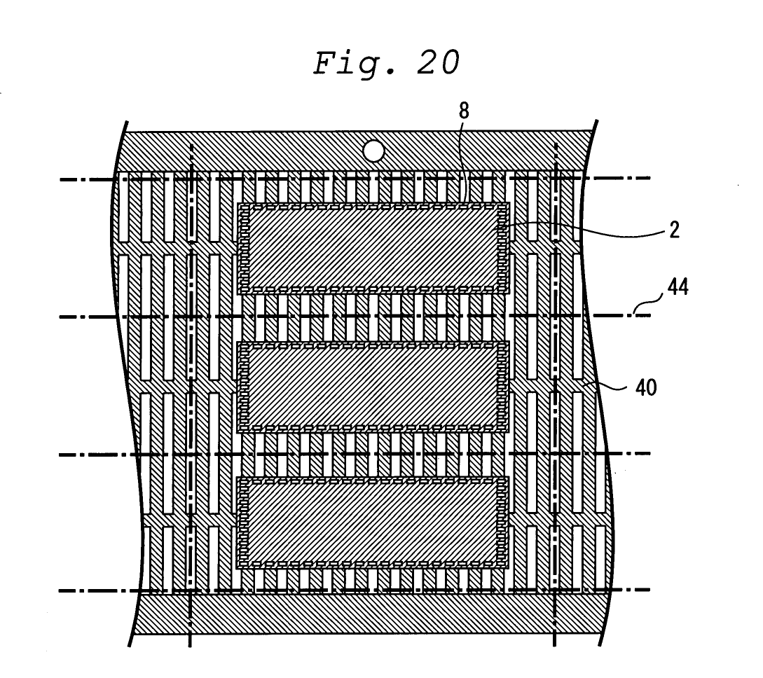

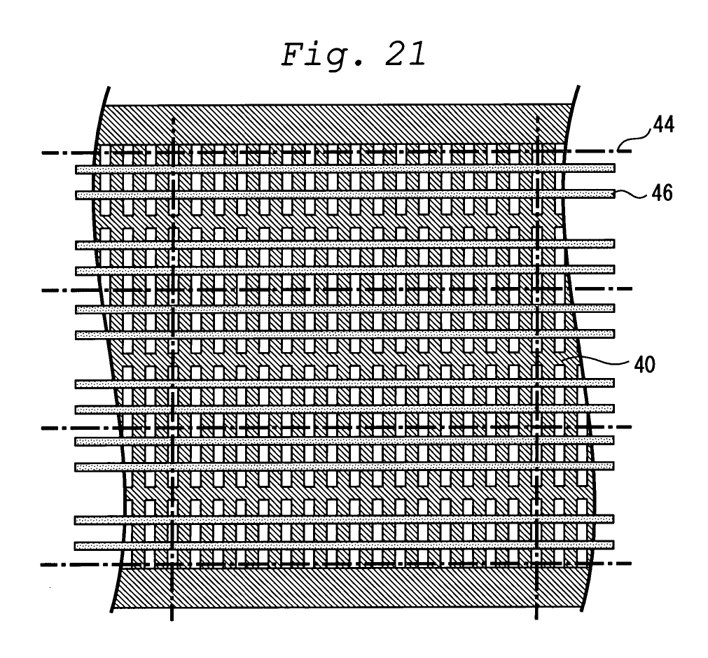

FIG. 19 is a flow diagram for illustrating the method for manufacturing a semiconductor device 400 according to the fourth embodiment of the present invention. FIGS. 20 to 22 are schematic diagrams for illustrating the state of the semiconductor device 400 in each manufacturing step.

The method for manufacturing a semiconductor device 400 according to the fourth embodiment of the present invention will be described in detail below referring to FIGS. 19 to 22.

First, as FIG. 20 illustrates, a plurality of semiconductor chips 2 are mounted on each island area 42 of the lead frame 410, and are fixed using a die-bonding material 6 (Step S2). At this time, the semiconductor chips 2 are mounted on the leads 40 in piles.

Next, the bonding pads 8 on each semiconductor chip 2 and leads 40 are wire-bonded with gold wires 10 (Step 4). At this time, an end of each of two gold wires 10 is connected to a portion of each lead 40 in vertical direction between chip-dicing lines 44 in the vertical direction and the leads 40 in the lateral direction (for convenience, the portion is referred to as a section of the leads 40) so as not to contact each other. The other end of each gold wire 10 is connected to a separate bonding pad 8. Specifically in this state, bonding pads 8 are short-circuited.

Next, the semiconductor chips 2 are subjected to mold sealing on the lead frame 410 with a sealing resin 12 (Step S6). Thereby, the semiconductor chips 2 are sealed on the lead frame 410. At this time, individual semiconductor chips 2 are not sealed, but the entire surface of the lead frame 410 is collectively resin-sealed. On the bottom surface of the lead frame 410, leads 40 are exposed out of the sealing resin 12. The trenches formed along the lead-dicing lines 46 of the lead frame 410 are also filled with the sealing resin 12.

Next, as FIG. 21 illustrates, the leads 40 are cut in the lateral direction along the lead-dicing lines 46 using a blade from the side of the bottom surface (Step S8). Here, each region between the chip-dicing lines 44 in the lateral direction and the leads 40 in the lateral direction are cut along two lead-dicing lines 46 in the lateral direction. Thereby, each lead 40 in each region between two chip-dicing lines 44 in the lateral direction is divided into five portions by four dicing lines 46. Thereby, the each of the sections of the lead 40 is divided into independent leads 40. Therefore, each of the two bonding pads 8 that has been connected to one section of the lead 40 is in the state connected to each of cut individual leads 40, and the sort-circuited state is released. The portion to which leads 40 in the vertical direction are intersecting the lead 40 in the lateral direction is left as it is. However, since no gold wires 10 are connected to this portion, and the sort-circuited state is also released even in the state wherein this portion is left as it is.

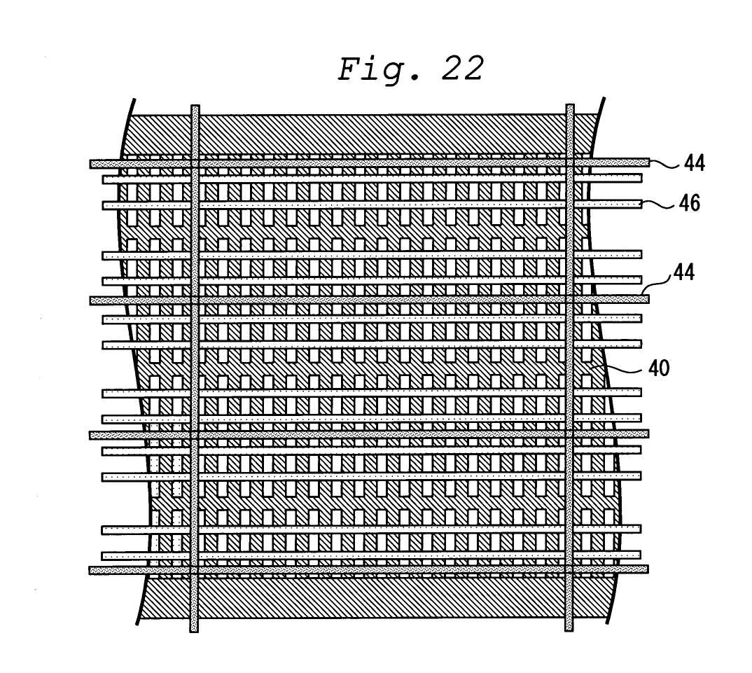

Next, the lead frame 410 is divided along the chip-dicing lines 44 into individual semiconductor devices 400 (Step S20). Here, as FIG. 22 illustrates, the lead frame 410 is divided along the chip-dicing lines 44 in vertical and lateral directions, into individual semiconductor devices 400. At this time, since the total of the lead frame 410 and the sealing resin 12 has a considerable thickness, dicing is performed from both the front and back sides of the semiconductor device 400. Thereby, semiconductor devices 400 each having the surface of the sealing resin 12 that has the marks of the blade in two directions, and the surface of the lead frame 40 that has the marks of the blade in one direction, can be formed.

Thereafter, each lead 40 is subjected to plating (Step S10). At this time, the number of leads 40 formed in each semiconductor device 400 and used as terminals is 16×2 in one side, and 16×4 in total. Therefore, it is sufficient to form exterior platings 14 on a total of 64 leads 40.

In the semiconductor device 400, as described above, the lead frame 410 is cut to use as the leads 40. Therefore, one type of lead plate 410 can correspond to a plurality of types of semiconductor chips 2 having different numbers of bonding pads 8. Thereby, the productivity of the lead frames 410 can be improved, and the production costs of the semiconductor devices 400 can be lowered.

In the semiconductor device 400, since the leads 40 are cut, no complicated steps for manufacturing the lead frame 410 are required. Therefore, the improvement of the productivity of the lead frame 410 can be achieved, leading to the reduction of the production costs of semiconductor devices.

In the fourth embodiment, each of a plurality of semiconductor chips 2 is mounted on each island area 42 on one lead frame, resin sealing or the like is performed, and after dicing predetermined parts of the leads 40, the lead frame is divided into individual semiconductor devices 400. Therefore, the manufacturing steps can be simplified, and the production costs can be lowered.

In the fourth embodiment, the case wherein each section of the leads 40 is divided into two portions in the lateral direction is described. However, the present invention is not limited thereto, but the number of cutting operations can be adjusted considering the required number of terminals for the number of electrodes in the semiconductor chip 2. Here, 16 vertically long leads 40 are formed in a chip, and are cut. However, the number of the leads 40 is not limited thereto. In the present invention, for example, the lead frames as described in the first to third embodiments can be formed sequentially.

In the fourth embodiment, the case wherein the leads are cut using a blade and the like is described. However, the present invention is not limited to such a cutting method, but other methods, such as etching, can also be used for cutting. The cutting using a blade is not limited to cutting both upward and downward, but cutting from one side can also be used. The cutting methods can be selected considering the thickness of the entire semiconductor device.

Also in the fourth embodiment, the case wherein trenches are formed on the surface of the lead frame 410 for mounting the semiconductor chips 2 corresponding to the lead-dicing lines 46 is described. However, the present invention is not limited thereto, but for example, no trenches may be formed.

Since other parts are same as those in the first to third embodiments, the description thereof will be omitted.

The features and the advantages of the present invention as described above may be summarized as follows.

According to one aspect of the present invention, leads in a lead frame used in a molded package can be formed also on the area to mount the semiconductor chip, and leads in this area can also be utilized as external terminals. Therefore, the lead frame can cope with increase in the number of leads, while suppressing the enlargement of the semiconductor device.

Another aspect of the present invention, after the leads have been connected to the electrodes of the lead frame with gold wires, and sealed with a resin, the leads are cut into individual terminals as required. Therefore, one type of lead frame can be used in various semiconductor chips having different number of electrodes, and the productivity of lead frames can be improved. Thereby, the production costs can be suppressed low even when the number of leads increases.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-347120, filed on Oct. 6, 2003 including specification, claims, drawings and summary, on which the Convention priority of the present application is based, are incorporated herein by reference in its entirety.

1. A lead frame used in the mold package of a semiconductor device, comprising a lead to be terminals in the semiconductor device, wherein
said lead can be divided by cutting into a plurality of parts that can be used as terminals.

2. The lead frame according to claim 1, wherein said lead is a plurality of lead wires arrayed in directions perpendicular to each peripheral side of said lead frame; and
at least one of said lead wires is disposed extending from the area whereon a semiconductor chip is mounted to the exterior of the area.

3. The lead frame according to claim 1, wherein said lead is plate larger than the lower surface of a semiconductor chip to be mounted.

4. The lead frame according to claim 3, wherein said lead is a plate having an opening in the location for mounting a semiconductor chip.

5. A semiconductor device comprising:
a semiconductor chip having a plurality of bonding pads,
a lead frame mounting said semiconductor chip, and including a lead to become terminals in the semiconductor device,
gold wires for electrically connecting said bonding pads to predetermined locations of said lead, and
a sealing member for sealing said semiconductor chip on said lead frame, wherein
said lead is divided into a predetermined number at predetermined locations after mounting said semiconductor chip, and are used as individual terminals corresponding to said bonding pads in a one-to-one manner.

6. The semiconductor device according to claim 5, wherein
said lead frame has a plurality of mounting portions for mounting said semiconductor chip; and
said semiconductor device is composed by further cutting said sealing member and said lead frame after dividing said leads, and a part of said sealing member and a part of said lead frame are exposed on the cutting surfaces of said semiconductor device.

7. The semiconductor device according to claim 6, wherein said sealing member exposed on said cutting surfaces has a blade mark cut in a plurality of cutting operations, and said lead frame exposed on said cutting surfaces has a blade mark cut in one cutting operation.

8. The semiconductor device according to claim 5, wherein
said lead is a plurality of lead wires arrayed in directions perpendicular to each peripheral side of said lead frame; and
at least one of said lead wires is disposed extending from the area whereon said semiconductor chip is mounted to the exterior of the area.

9. The semiconductor device according to claim 5, wherein said lead is a plate larger than the lower surface of said semiconductor chip, and
said semiconductor chip is mounted on said plate.

10. The semiconductor device according to claim 9, wherein said lead is a plate having an opening in the location for mounting said semiconductor chip.

11. A method for manufacturing a semiconductor device comprising:
a mounting step for mounting a semiconductor chip that has a plurality of bonding pads on a predetermined location of a lead frame;
a connecting step for connecting said bonding pads to a lead of said lead frame by a gold wire;
a sealing step for sealing said semiconductor chip on said lead frame using a sealing member; and
a cutting step for cutting predetermined locations of said lead frame to divide said lead into individual terminals corresponding to said bonding pads in a one-to-one manner.

12. The method for manufacturing a semiconductor device according to claim 11, wherein
said lead frame comprises a plurality of mounting portions for mounting a plurality of semiconductor chips;
in said mounting step, each of said semiconductor chips is mounted on each of said mounting portion; and
said method for manufacturing a semiconductor device further comprises, after said cutting step, a dividing step for cutting predetermined locations of said lead frame and said sealing member to divide into individual semiconductor devices.

13. The method for manufacturing a semiconductor device according to claim 11, wherein
said lead is a plurality of lead wires arrayed in directions perpendicular to each peripheral side of said lead frame; and
at least one of said lead wires is disposed extending from the area whereon said semiconductor chip is mounted to the exterior of the area.

14. The method for manufacturing a semiconductor device according to claim 11, wherein
said lead is a plate larger than the lower surface of said semiconductor chip, and
in said cutting step, said lead is cut in grid-like pattern.

15. The method for manufacturing a semiconductor device according to claim 14, wherein
said lead is a plate having an opening in the location for mounting said semiconductor chip.
